(19) United States
(12) Patent Application Publication
(10) Pub. No.: US 2007/0197020 A1
(43) Pub. Date: Aug. 23, 2007

(54) Inline method to detect and evaluate early failure rates of interconnects

(75) Inventor: Deepak A. Ramappa, Dallas, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/356,702

(22) Filed: Feb. 17, 2006

(51) Int. Cl. H01L 21/4763

(52) U.S. Cl. 438/622

(57) ABSTRACT

A method of detecting interconnect defects in a semiconductor device. The method comprises positioning a portion of a semiconductor substrate, having a plurality of interconnects, in a field of view of an inspection tool. A voltage contrast image of the portion is produced. The voltage contrast image is obtained using a collection field that is at least about 1 percent different than an incident field. The method further comprises using the voltage contrast image to determine defective ones of the interconnects.

### TECHNICAL FIELD

The invention is directed to a method and system for detecting interconnect defects in semiconductor devices to facilitate the manufacture of integrated circuits comprising such devices.

### BACKGROUND

Interconnects are commonly used to electrically connect electronic devices, such as capacitors or transistors. Unfortunately, situations arise where a problem in fabrication results in a faulty or defective interconnect. Traditional methods and instruments to detect metal interconnect defects have typically been performed on a completed device, that is, after completing all front-end-of-line (FEOL) and back-end-of-line (BEOL) processes, as part of quality assurance monitoring. Examples of conventional detection methods include assessing the electrical or logic performance characteristics of the device by e.g., measuring leakage current or bit failure rates, or by inspecting scanning electron microscopic images of the device. There is a continuing need to develop methods to detect interconnect reliability defects in the BEOL process in order to further reduce resource expenditure on the fabrication of devices that are destined to be defective.

Accordingly, what is needed in the art is a method and system for detecting interconnect defects in a semiconductor device during the manufacture of an integrated circuit that addresses the drawbacks of the prior art methods and devices.

### SUMMARY

The invention provides in one embodiment, a method of detecting interconnect defects in a semiconductor device. The method comprises positioning a portion of a semiconductor substrate, having a plurality of interconnects, in a field of view of an inspection tool. A voltage contrast image of the portion is produced. The voltage contrast image is obtained using a collection field that is at least about 1 percent different than an incident field. The method further comprises using the voltage contrast image to determine defective ones of the interconnects.

Another embodiment is an inspection system for detecting interconnect defects in a semiconductor device. The system comprises an inspection tool, a stage and a control module. The inspection tool comprises an electron-beam source and a collection unit. The stage is configured to position a portion of a semiconductor substrate, having a plurality of interconnects, in a field of view of the inspection tool. The control module is configured to adjust an electron-beam landing energy applied by the electron-beam source to the semiconductor device and thereby produce an incident field on a surface of the semiconductor substrate. The control module is also configured to adjust a detection potential applied to the collection unit to thereby produce a collection field that is at least about 1 percent different than the incident field. The control module is further configured to produce a voltage contrast image of the portion, and to use the voltage contrast image to determine defective ones of the interconnects.

Another embodiment is a method of manufacturing an integrated circuit. The method comprises forming a semiconductor device on a semiconductor substrate and forming interconnects for the semiconductor device. The method further comprises inspecting the interconnects for defects by the above-described method.

### BRIEF DESCRIPTION OF THE DRAWINGS

FIG. 1 illustrates by flow diagram, selected steps of an example implementation of a method of detecting interconnect defects in a semiconductor device according to the principles of the present invention;

FIG. 2 presents a block diagram of an example inspection system of the present invention for detecting interconnect defects in a semiconductor device; and

FIGS. 3-5 illustrate cross-sectional views of selected steps in an example implementation of a method of manufacturing an integrated circuit according to the principles of the present invention.

### DETAILED DESCRIPTION

The term interconnect as used herein refers to any metal contact, plug, via, or line that provides an electrically conductive path that connects one component of a semiconductor device to another component of a semiconductor device. For the purposes of the present invention a defective interconnect, or interconnect defect, is defined as an interconnect that has a lower electrical conductivity, or higher resistance, than designed for that particular interconnect structure in a semiconductor device.

In some cases, the faulty interconnect is classed as a yield-defect. A yield defect is non-conductive immediately after its fabrication. In other cases, the faulty interconnect is classed as an early failure, or reliability defect. An interconnect with a reliability defect may initially be conductive and functional in the device, but then after a period of use becomes non-conductive and the device fails to function earlier than expected. Both of these kinds of defects can contribute to the production of unacceptably low numbers of devices that operate within performance specifications.

The recent introduction of electron-beam passive voltage contrast detection methodology and instrumentation has greatly facilitated the measurement of interconnect yield defects during in the manufacturing process. Improvements in voltage contrast imaging have reduced the time to measure interconnect defects, thereby allowed such imaging as part of FEOL processes. The interconnect defects detected by this approach, however, are limited to detecting yield defects manifesting, for example, as fully non-conductive interconnects in semiconductor devices.

The invention is based at least in part on the recognition that previous approaches to detect interconnect defects are inadequate because they do not predict reliability defects that can manifest after FEOL or BEOL processing. It was further recognized that interconnects destined to become reliability defects can still be partially conductive after FEOL and BEOL processing and therefore go undetected using conventional approaches. In some process flows, however, the interconnect reliability defects can malfunction after a semiconductor device has being fabricated or even after being placed in use for a period.

Reliability defects can go undetected because existing methods and tools for detecting defects require the existence of a non-conductive interconnect in the semiconductor device being inspected. This follows, because conventional methods using e.g., passive voltage contrast imaging and tools rely on there being no or very low numbers of secondary electrons emitted from a semiconductor device having a defective interconnect, as compared to analogous neighboring semiconductor devices with fully conductive interconnects.

Embodiments of the invention overcome this limitation by providing a method and system to detect both yield and reliability interconnect defects. The ability to accurately predict potential interconnect reliability defects advantageously allows accelerated learning and correction of problematic integrated circuit manufacturing flow processes, thereby reducing resource expenditure on the fabrication of devices that are destined to be defective.

The invention is particularly advantageous for detecting defects in copper interconnects. It should be understood, however, that the scope of the present invention includes detecting such defects in a semiconductor device comprising any conductive interconnect, including metal or metal alloy interconnects.

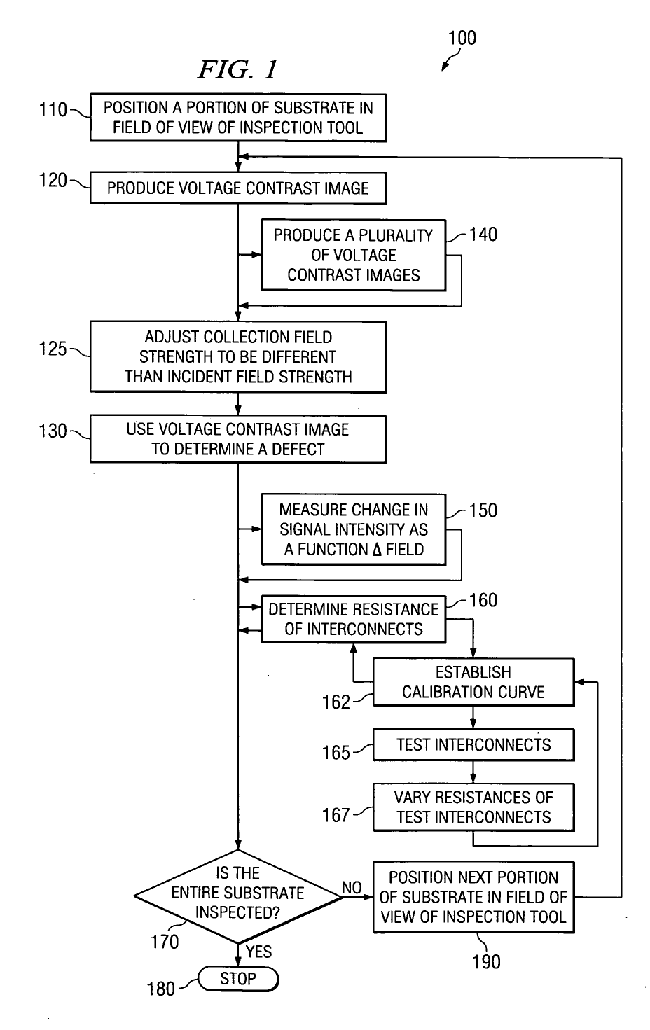

One embodiment is a method of detecting interconnect defects in a semiconductor device. FIG. 1 illustrates, by flow diagram, selected steps in an exemplary method 100 performed according to the principles of the present invention. The method comprises, in step 110, positioning a portion of a semiconductor substrate in a field of view of an inspection tool.

The semiconductor substrate, such as a silicon wafer, comprises a plurality of integrated circuit (IC) dies. Each of the IC dies has interconnects formed on components of the semiconductor devices of the IC. For example, the semiconductor devices can comprise nMOS, pMOS transistors or CMOS devices, having metal interconnects, such as contacts, formed on source and drain structures and gate structures.

Those skilled in the art would be familiar the use of an electron-beam source to raster an incident electron-beam over the surface of the semiconductor substrate within a particular field of view (FOV) that is appropriate for the inspection tool being used. For example, an eS20™ inspection tool (KLA-Tencor Inc., San Jose, Calif.) can have a FOV of about 2 by 2 microns. The portion of the semiconductor substrate selected for voltage contrast imaging is equal to or less than the field of view selected for the inspection tool.

The method also comprises producing a voltage contrast (VC) image, in step 120, under conditions where the image is obtained using a collection field that is different than an incident field. The term incident field as used herein refers to an electrical field associated with a potential developed on the surface of the semiconductor substrate as a result of the impinging rastering incident electron-beam. The term collection field as used herein refers to an electrical field associated with a potential created in a space above the semiconductor substrate to attract and enhance the detection of secondary electrons that are generated. Both the collection field and incident fields have a positive charge. Thus, in the context of the present invention, a collection field that is different than the incident field means that the collection field is at least about 1 percent more positive or more negative than the incident field. In certain preferred embodiments, the collection field is at least about 8 percent weaker than the incident field.

In some preferred embodiments the collection field is adjusted to be different than the incident field, in step 125, by adjusting one or both of a landing energy associated with the incident electron beam or a detection potential associated with detection electrons via a collection unit of the inspection tool. The quantity of secondary electrons produced at the surface of the semiconductor substrate depends upon the landing energy, that is, the amount of energy in the incident electron-beam at the surface of the semiconductor surface. The amount of secondary electrons detected can be increased by e.g., applying the detection potential to a grid or mesh of the collection unit. A positive potential applied to the grid or mesh attracts the negatively charged secondary electrons into the collection unit.

In certain advantageous embodiments of the method 100, the detection potential used to generate the collection field is weaker than the electron-beam landing energy that generates the incident field. The extent to which the detection potential is made weaker than the electron-beam landing energy depends upon the composition of the semiconductor substrate and the semiconductor device. For example, in some embodiments directed to the detection of defects in interconnects that are copper contacts, the detection potential is at least about 20 electron-Volts less, and in some case about 800 electron-Volts less, than the electron-beam landing energy.

Of course, in other embodiments the detection potential can be made stronger than the electron-beam landing energy. For example, the detection potential can range from about 920 to about 940 electron-Volts with the electron-beam landing energy being about 900 electron-Volts. Such embodiments may be useful in cases when short-circuit types of reliability defects are being targeted. Two interconnect features affected by a shorting type of reliability defect tend to look brighter (voltage contrast bright). When a beam rasters a given area, the secondary electrons generated can be generated not only on copper and tungsten surfaces but also on the surface of dielectrics surrounding the metal interconnects. For example, if copper interconnects or tungsten contacts are fabricated within dielectrics that have an intrinsic characteristic of generating a significantly larger amount of secondary electrons compared to normal dielectrics, then the surface of the dielectric will also look bright. This can reduce the brightness detection efficiency or sensitivity. Therefore, to improve the sensitivity in such a situation, the detection potentials are increased so as to attract or extract away more electrons from the surface.

The method 100 further comprises using, in step 130, the voltage contrast image to determine an interconnect defect. The inspection tool is configured to contrast differences in signal intensities received from different areas of the semiconductor device. The tool is typically adjusted to display gray-scale voltage contrast images in which fully conductive and functional interconnects appear as an intense white signal, while insulating material surrounding the interconnect appear as a low intensity dark signal. A defective interconnect has reduced electrical conductivity and therefore has lower signal intensity than adjacent interconnects with no defect. Depending on its conductivity, the signal intensity obtained from a defective interconnect can range from a low intensity dark signal similar to that obtained from the insulating material surrounding the interconnect, to slightly lower than the intense white signal obtained from adjacent interconnects with no defect. Of course, the inspection tool could be configured to display the signal from fully conductive and functional interconnects as dark spots in a reverse contrast image, or as a particular color in a color image, where colors are coded according to a predefined range of signal intensities.

To determine an interconnect defect in step 130, the inspection tool is configured to display the voltage contrast image obtained in step 120 to have a signal corresponding to the interconnects that are yield defects or reliability defects. As noted above, typically the voltage contrast image is configured to depict no signal intensity for yield defects and lower signal intensity for reliability defects, as compared to neighboring interconnects having no defects. The ability to detect both interconnect yield defects or interconnect reliability defects using the method of the present invention is in contrast to conventional methods. Conventional methods of defect detection are capable of detecting and displaying signals corresponding to yield defects only.

One skilled in the art would be familiar with the myriad of ways an interconnect defect can form. Consider, for instance, a copper contact that is formed by conventional processes. The contact can be formed in an opening in a substrate, by e.g., depositing a barrier layer and a copper seed layer in the opening by a vacuum process, such as physical vapor deposition (PVD) or chemical vapor deposition (CVD), and then depositing a thick copper layer in the opening over the seed layer by a wet process, such as electrochemical deposition (ECD).

In some cases, organic contaminants from e.g., photo-resist layers may form on the seed layer the opening, or the copper seed layer can oxidize. The presence of such deposits in the opening can exacerbate the formation of voids in the thick electroplated copper layer. Voids in the copper contact, in turn, can reduce the conductivity of the contact thereby making it defective. A large void can render the contact substantially non-conductive resulting in an interconnect having a yield defect. A smaller void that renders the contact partially conductive has the potential to result in an interconnect having a reliability defect.

It is emphasized that the characterization of an interconnect defect as a yield or a reliability defect refers to the status of the defect at the time the method 100 is performed. Preferably, the method 100 is performed as part of the FEOL process, and even more preferably, after completing all steps in formation of interconnects in the FEOL process. In some cases, however, additional fabrication steps during BEOL processing, or during actual use of the final device can cause a partially conductive interconnect, e.g., a reliability defect, to become a fully non-conductive interconnect, resulting in a device malfunction. Preferably, the voltage contrast image obtained in step 120 can detect both yield and reliability defects as part of the BEOL process. The voltage contrast image obtained in step 120 can thereby provide an early failure indicator of interconnects having the potential to cause the device to not operate within performance specifications.

In some cases it is advantageous to obtain, in step 140, a plurality of voltage contrast images for the same portion of the semiconductor substrate. Preferably, each one of the plurality of voltage contrast images is obtained using one of a set of collection fields that range from less different to more different than the impinging field.

Similar to step 120, the plurality of voltage contrast images produced in step 140 can be obtained by adjusting one or both of the impinging and collection fields. In some preferred embodiments, for example, the collection fields could range from less positive to more positive than the impinging field. Or, the collection field could range from less negative to more negative than the impinging field. In the former case, for instance, the detection potential can range from about 40 electron-Volts to about 200 electron-Volts less positive than said electron-beam landing energy voltage.

The inspection tool can be configured to display the plurality of voltage contrast images with signals corresponding to interconnect defects. Such a display of the plurality of images is advantageous for a new fabrication process, where it is uncertain what combination of impinging and collection fields are appropriate to detect interconnect defects that correspond to yield and reliability defects.

In some cases, the inspection tool is configured, in step 150, to measure a change in intensity of the signals as a function a difference in the field strength (Δ field) between the collection field and the impinging field. In instances where the impinging field is held constant and the collection field is adjusted between scans, it is acceptable to measure the change in intensity of the signals as a function of the changing collection field. In still other instances, it is acceptable to measure the change in intensity of the signals as a function of the changing detection potentials used to generate the collection fields.

In some instances, the change in intensity of the signal corresponding to the interconnect defects as function of the Δ field may be used to predict a severity of the defect. In some cases, it is sufficient for the severity of the defect to simply be a characterization of the interconnect defect as a yield and reliability defect, similar to that obtained in step 120. In other cases, however, it is desirable to characterize the defect's severity as a probability that, after further processing, reliability defects will form into a fully non-conductive defect that causes a short circuit or other malfunction in the semiconductor device.

In still other cases, the inspection tool is configured, in step 160, to determine an electrical resistance of the plurality of interconnects from the voltage contrast image. The intensity of the signals from defective interconnects obtained under predefined conditions of the collection field and incident field can be related to a resistance of the interconnect. A difference in the field strength (Δ field) between the collection field and the impinging field will also lead to changes in the intensity of the signals from interconnects. The change in intensity in this case is not necessarily directly related to the interconnect resistances. Rather, the change in intensity can also be a function of the type of interconnect material, its secondary electron generation efficiency and the nature of the surface of the dielectric surrounding the interconnects. Therefore appropriate calibration procedures may be needed to determine a resistance.

The relationship between an interconnect's voltage contrast signal intensity and its resistance can be established using suitable calibration standards. It can be advantageous, for instance, in step 162, to establish a calibration curve relating test electrical resistances to test voltage contrast image intensities. The test voltage contrast image intensities can be obtained in step 165 from test interconnects formed on a setup or calibration wafer, or, from interconnects in a designated test areas of a production wafer. Alternatively, test voltage contrast image intensities can be obtained from integrated circuit on production wafers that are sacrificed for the purposes of obtaining the calibration.

In step 167, the resistance can be varied by, e.g., varying an amount of dopants in the semiconductor substrate underlying the test interconnects. Preferably, the test interconnects have the same geometry and composition as the interconnects used in the semiconductor device. The resistance of the test interconnects can be measured using conventional procedures using current voltage probing methods, well known to those skilled in the art. For example, a given current is forced through the interconnect and the voltage is measured across the interconnect ends. The resistance of the interconnect is the average slope of a plot of current versus voltage. These current and voltages curves can be extracted using electrical probe machines that are well known to those skilled in the art.

After the plurality of different test electrical resistances and test voltage contrast images intensities are produced, the calibration curve can be ascertained in step 162 by graphical or numerical analysis. For example, the plurality electrical resistances and image intensities can be plotted, or, a function can be fitted to these data to establish the calibration curve. In some cases, the calibration curve comprises a plot or linear regression fit of the logarithm of the interconnect's resistance versus the percentage change in the image intensity from interconnects (e.g., with the highest intensity defined as 100 percent and the lowest intensity defined as 0 percent).

If it is determined in step 170 that the entire semiconductor substrate has been inspected, then the method 100 is halted at step 180. Alternatively, if the entire semiconductor substrate has not been inspected, then in step 190, a next portion of the semiconductor substrate is positioned in the field of view of the inspection tool, and steps 120 through 170 are repeated as appropriate on the next portion.

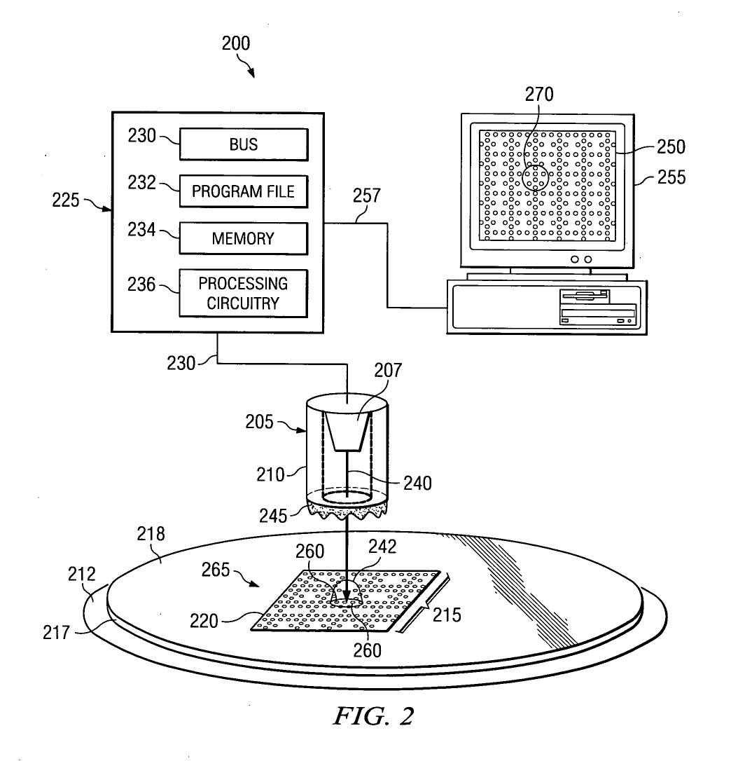

Yet another aspect of the present invention is an inspection system for detecting interconnect defects in a semiconductor device. FIG. 2 presents a block diagram of an exemplary inspection system 200 of the present invention. The inspection system 200 comprises an inspection tool 205. The inspection tool 205 comprises an electron-beam source 207 and a collection unit 210. The inspection system 200 also comprises a stage 212 configured to position a portion 215 of a semiconductor substrate 217 having a surface 218 in a field of view 220 of the inspection tool 205. For the embodiment shown in FIG. 2 the portion 215 of the substrate 217 selected for inspection is substantially the same size as the field of view 220.

The inspection system 200 further comprises a control module 225. The control module 225 can comprise any conventional processing device capable of performing operations needed to control the inspection of semiconductor devices, and includes components well known to those skilled in the art. Such components can include a bus 230 to send commands to and receive data from the inspection tool 205, a program file 232 to control the inspection tool 205, a memory 234 to hold data obtained by the inspection tool 205, and processing circuitry 236 to perform mathematical operations on the data.

The control module 225 is configured to adjust a landing energy of an incident electron-beam 240 applied by the electron-beam source 207 to the semiconductor substrate 217 and thereby produce an incident field 242 on the substrate surface 218. The control module 225 is also configured to adjust a detection potential applied to the collection unit 210 to thereby produce a collection field 245 that is different than the incident field 242. The control module 225 is further configured to produce a voltage contrast image 250 of the portion 215. As illustrated in FIG. 2, the voltage contrast image 250 can be displayed on a video monitor 255 that is coupled to the control module 225 via a data cable 257.

The control module 225 is also configured to use the voltage contrast image 250 to determine one or more interconnect defects 260 in a semiconductor device 265. Any of the embodiments of the methods and components discussed above and illustrated in FIG. 1, can be used by the inspection system 200, to determine and characterize the interconnect defect. Consider the following example of how the control module 225 can be configured to convert a data set from the collection unit 210 into a voltage contrast image 250 of the portion 215 of the substrate 217.

The program file 232 of the control module 230 can configure the inspection tool 205 to produce a collection field 245 that is at least about 8 percent different (e.g., weaker or stronger, but preferably weaker) than the incident field 242. A data set obtained from the inspection tool 205 using these relative field strengths is stored in the memory 234 of the control module 230. The processing circuitry 236 operates on the data set to convert it into the voltage contrast image 250 of the portion 215. The voltage contrast image 250 has signals 270 corresponding to interconnect defects 260 that are yield or reliability defects.

The control module 225 can be configured to obtain a plurality of voltage contrast images of the same portion 215 of the substrate 217 in order to further characterize the severity of the interconnect defects. To minimize the time to collect such data, it is advantageous for the control module 225 to be configured to direct the inspection tool 205 to sequentially collect the data sets corresponding to each of the plurality of images from the same portion 215 of the substrate 217 before commanding the stage 212 to move a different portion of the substrate 217 into the field of view 220.

The control module 225 can also be configured to determine the electrical resistance of one or more of the interconnects of the semiconductor substrate 217, including the interconnect defects 260. For instance, calibration information relating the intensity of an interconnect's voltage contrast image signal to its resistance can be stored in the memory 234 of the control module 230. The processing circuitry 236 operates on the signals 270 of the voltage contrast image 250 to determine the resistance of the interconnect defects 260.

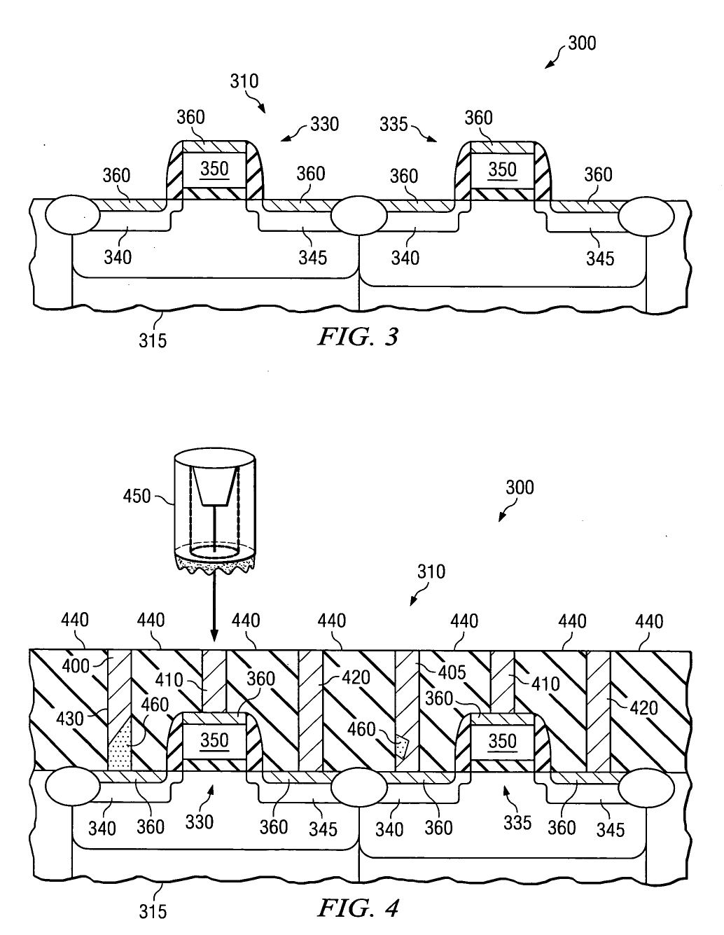

Still another aspect of the present invention is a method of manufacturing an integrated circuit. FIGS. 3-5 illustrate cross-sectional views of selected steps in an exemplary method of manufacturing an integrated circuit 300 according to the principles of the present invention. Turning first to FIG. 3, illustrated is the partially completed integrated circuit 300 after forming a semiconductor device 310 on a semiconductor substrate 315. Some preferred embodiments of the semiconductor device 310 comprise an nMOS transistor 330 and a pMOS transistor 335 that form a semiconductor device 310 that is a CMOS device. However, the semiconductor device can also comprise Junction Field Effect transistors, bipolar transistors, biCMOS transistors, or other conventional device components, or combinations thereof.

Any conventional methods and materials can be used to fabricate the semiconductor device 310. Typically forming the semiconductor device 310 comprise steps in a FEOL process. Included in the FEOL process are the formation of source and drain structures 340, 345, gate structures 350 and metal silicide electrodes 360.

With continuing reference to FIG. 3, FIG. 4 illustrates the integrated circuit 300 after forming interconnects 400, 405, 410, 420, such as tungsten or copper contacts in openings 430 formed in an insulating layer 440, such as a silicon dioxide layer, located over the semiconductor device 320 and connected to the metal silicide electrodes 360. FIG. 4 further illustrates inspecting the semiconductor device 310 for interconnect defects. The defect can be a fully non-conductive interconnect 400, that is, a yield defect, or a partially conductive interconnect 405, that is, a reliability defect.

Any of the above-described methods and systems and their component parts, such as an inspection tool 450, can be used to facilitate the inspection. For instance, as discussed in the context of FIGS. 1-2, the inspection can comprise positioning a portion of the semiconductor substrate 315 in a field of view of the inspection tool 450, producing a voltage contrast image using a collection field that is different than an incident field, and using the voltage contrast image to determine a presence of a interconnect defect 400, 405 of the semiconductor device 310.

The inspection can be conducted once or multiple times at the completion of either the FEOL or BEOL processes or at intermediated stages in these processes. Preferably, the inspection comprise steps early in the BEOL process, because then later remaining steps in the BEOL process can be halted if interconnect defects 400, 405 are detected, thereby saving manufacturing resources and time. Alternatively, one or more steps in the manufacturing process can be modified if the interconnect defect 400, 405 is detected. One of ordinary skill in art would be aware of the multitude of processing errors and their correction that could be made to reduce or eliminate interconnect defects. For example, the tool for removing photoresist from the via opening 430 may not have an adequate cleaning cycle, resulting in a void 460 being formed in the interconnect 360, 365. Alternatively, barrier material deposited in a via opening 430 may not have the appropriate thickness, or an oxide layer may have been inadvertently formed in the via opening 430.

As illustrated in FIG. 4, in some cases, the inspection is conducted after only a portion of BEOL process is completed, e.g., the formation of via interconnects 400, 405, 410, 420, in a first insulating layer 440 over the semiconductor device 310. If no interconnect defect is detected at this stage of the BEOL process, or if the defect is judged to be not severe, then the manufacture of the integrated circuit 300 can be continued. Of course, the characterization of a defect as being not severe based on the inspection will be informed and refined by the experiences gathered while manufacturing a plurality of integrated circuits using the same or similar processes.

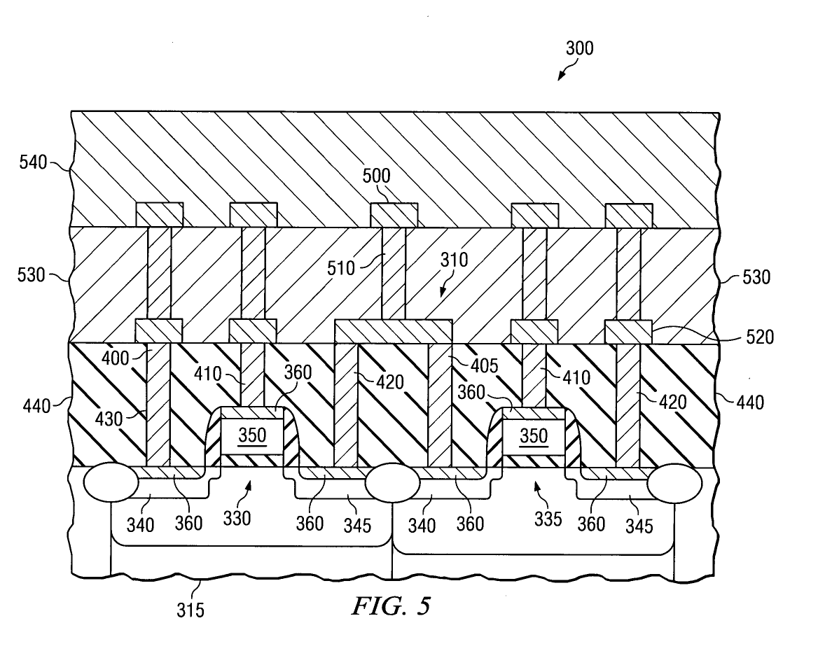

FIG. 5 illustrates the integrated circuit after forming additional interconnects, e.g., one or more interconnect metals lines 500, 510, 520 in one or more insulated metal layers 530, 540 to interconnect the semiconductor device 310 and thereby to form an operative device. The inspection can be repeated any number of times to determine if defects exist at this or further levels of interconnect structures. For instance, in some preferred embodiments, the inspection is conducted after forming via interconnects 400, 405, 410, 420 but before forming the interconnect metals lines 500, 510, 520 in the first metal layers 530. In other cases, the inspection is conducted after forming the first metal layer 530, but before forming the second metal layer 540.

Those skilled in the art to which the invention relates will appreciate that other and further additions, deletions, substitutions and modifications may be made to the described example embodiments, without departing from the invention.

1. A method of detecting interconnect defects in a semiconductor device, comprising:
positioning a portion of a semiconductor substrate having a plurality of interconnects in a field of view of an inspection tool;
producing a voltage contrast image of said portion, wherein said voltage contrast image is obtained using a collection field that is at least about 1 percent different than an incident field; and
using said voltage contrast image to determine defective ones of said interconnects.

2. The method of claim 1, wherein said collection field is weaker than said incident field.

3. The method of claim 1, wherein said collection field is stronger than said incident field.

4. The method of claim 1, wherein a detection potential used to generate said collection field is less than an electron-beam landing energy voltage that generates said incident field.

5. The method of claim 4, wherein said detection potential is at least about 20 electron-Volts less than said electron-beam landing energy voltage.

6. The method of claim 1, wherein said inspection tool is configured to display said voltage contrast image with signals corresponding to said defective interconnects that are reliability defects.

7. The method of claim 1, further comprising determining an electrical resistance of said plurality of interconnects from said voltage contrast image.

8. The method of claim 7, wherein determining said electrical resistance comprises establishing a calibration curve relating test electrical resistances to test voltage contrast image intensities.

9. The method of claim 8, wherein a plurality of different ones of said test electrical resistance and said test voltage contrast image intensities are produced by varying an amount of dopant in a test semiconductor substrate underlying a plurality of test interconnects.

10. The method of claim 1, wherein said voltage contrast image is one of a plurality of voltage contrast images for said portion, and each one of said plurality of voltage contrast images is obtained using one of a set of collection fields ranging from less different to more different than said impinging field; and
said inspection tool is configured to display said plurality of voltage contrast images having signals corresponding to said defective interconnects and to measure a change in intensity of said signals as a function of a difference between said collection field and said impinging field.

11. An inspection system for detecting interconnect defects in a semiconductor device, comprising:
an inspection tool comprising an electron-beam source and a collection unit;
a stage configured to position a portion of a semiconductor substrate having a plurality of interconnects in a field of view of said inspection tool; and
a control module configured to:
adjust an electron-beam landing energy applied by said electron-beam source to said semiconductor device and thereby produce an incident field on a surface of said semiconductor substrate;
adjust a detection potential applied to said collection unit to thereby produce a collection field that is at least about 1 percent different than said incident field; and
produce a voltage contrast image of said portion, and use said voltage contrast image to determine defective ones of said interconnects.

12. The system of claim 11, wherein said collection field weaker than said incident field.

13. The system of claim 11, wherein said collection field stronger than said incident field.

14. The system of claim 11, wherein a detection potential used to generate said collection field is less than an electron-beam landing energy voltage that generates said incident field.

15. The system of claim 11, wherein said control module is further configured to convert a data set from said collection unit into a voltage contrast image of said portion, said voltage contrast image having signals corresponding to said defective interconnects that are yield or reliability defects.

16. The system of claim 15, wherein said control module is further configured to direct said inspection tool to move a different portion of said substrate into said field of view after collecting said data set.

17. A method of manufacturing an integrated circuit comprising:
forming a semiconductor device on a semiconductor substrate;
forming interconnects for said semiconductor device; and
inspecting said interconnects for defects by:
positioning a portion of said semiconductor substrate in a field of view of an inspection tool;
producing a voltage contrast image of said portion, wherein said voltage contrast image is obtained using a collection field that is at least about 1 percent different than an incident field; and
using said voltage contrast image to determine the presence of an interconnect defect in said semiconductor device.

18. The method of claim 17, wherein said inspecting of said semiconductor device comprise steps in a back-end-of-line process.

19. The method of claim 18, wherein further back-end-of-line processing of said semiconductor device is halted if said interconnect defect is detected.

20. The method of claim 17, wherein one or more steps in said back-end-of-line process are modified if said interconnect defect is detected.
